(19) United States
(12) Patent Application Publication
(10) Pub. No.: US 2022/0082176 A1
(43) Pub. Date: Mar. 17, 2022

(54) VALVE DEVICE, FLOW CONTROL METHOD, FLUID CONTROL DEVICE, SEMICONDUCTOR MANUFACTURING METHOD, AND SEMICONDUCTOR MANUFACTURING APPARATUS

(71) Applicant: FUJIKIN INCORPORATED, Osaka (JP)

(72) Inventors: Ryutaro TANNO, Osaka (JP); Toshihide YOSHIDA, Osaka (JP); Daihi TSUCHIGUCHI, Osaka (JP); Yuya SUZUKI, Osaka (JP); Kenta KONDO, Osaka (JP); Tomohiro NAKATA, Osaka (JP); Tsutomu SHINOHARA, Osaka (JP); Masahiko TAKIMOTO, Osaka (JP)

(73) Assignee: FUJIKIN INCORPORATED, Osaka (JP)

(21) Appl. No.: 17/425,448

(22) PCT Filed: Jan. 23, 2020
(86) PCT No.: PCT/JP2020/002341

§ 371 Date: Jul. 23, 2021

(30) Foreign Application Priority Data
Jan. 31, 2019 (JP) 2019-015355

(51) Int. Cl. F16K 31/00; F16K 31/122; F16K 7/17; F16K 37/00

(52) U.S. Cl. CPC F16K 31/004; F16K 37/0033; F16K 7/17; F16K 31/1225

(57) ABSTRACT

A valve device with which a flow rate can be adjusted precisely includes: an operating member for operating a diaphragm provided in such a way as to be capable of moving between a closed position in which the diaphragm closes a flow path and an open position in which the diaphragm opens the flow path; a main actuator for moving the operating member to the open position or the closed position in response to the pressure of a supplied driving fluid; an adjustment actuator for adjusting the position of the operating member positioned in the open position; and a position detecting mechanism for detecting displacement of the operating member with respect to a valve body.

### TECHNICAL FIELD

The present invention relates to a valve device, and a flow control method, a fluid control device and a semiconductor manufacturing method using the valve device.

### BACKGROUND ART

In the semiconductor manufacturing process, in order to supply accurately metered process gases to a processing chamber, a fluid control device integrated with various fluid control devices such as open-close valves, regulators, and mass flow controllers is used.

Usually, a process gas outputted from the above fluid control device is directly supplied to a processing chamber, but in the processing process of depositing a film on a substrate by the atomic layer deposition (ALD) method, in order to stably supply the process gas, the process gas supplied from the fluid control device is temporarily stored in a tank as a buffer, and valves provided in the immediate vicinity of the processing chamber are frequently opened and closed to supply the process gas from the tank to the processing chamber in a vacuum atmosphere. See, for example, Patent Literature 1 as a valve provided in the immediate vicinity of the process chamber.

The ALD method is one of chemical vapor deposition methods, in which two or more types of process gases are alternately flowed on the substrate surface under film-forming conditions of temperature and time etc. to react with atoms on the substrate surface to deposit a film layer by layer, and in terms of film quality, since every atomic layer can be controlled, a uniform film thickness can be formed and a film can be grown very densely.

In the semiconductor manufacturing process by the ALD method, it is necessary to precisely adjust the flow rate of the process gas.

### PATENT LITERATURE

PTL 1: Japanese Laid-Open Application No. 2007-64333

PTL 2: International Publication No. WO2018/088326

### SUMMARY OF INVENTION

### Technical Problem

In an air-driven diaphragm valve, the flow rate changes with time by such causes as deformation of the resin valve seat over time, expansion or contraction of the resin valve seat due to heat changes.

Therefore, in order to more precisely control the flow rate of the process gas, it is necessary to adjust the flow rate according to the change with time of the flow rate.

The applicants have proposed in Patent Literature 2 a valve device provided with an adjustment actuator for adjusting the position of an operating member that operates a diaphragm, in addition to a main actuator operable by a pressure of supplied driving fluid, so as to automatically adjust the flow rate with precision.

Conventionally, to the valve device disclosed in Patent Literature 2, there has been a demand to detect the opening degree of the diaphragm as a valve element and to control the flow rate more precisely.

An object of the present invention is to provide a valve device which can adjust the flow rate precisely.

Another object of the present invention is to provide a flow control method, a fluid control device, a semiconductor manufacturing method and a semiconductor manufacturing apparatus using the above valve device.

### Solution to Problem

The valve device according to the present invention comprises: a valve body that defines a flow path through which a fluid flows and an opening that opens externally in a middle of the flow path;
a diaphragm that covers the opening, separates the flow path from the outside, and contacts to and separates from the periphery of the opening to open and close a flow path as a valve element,
an operating member for operating the diaphragm provided in such a way as to be capable of moving between a closed position in which the diaphragm closes the flow path and an open position in which the diaphragm opens the flow path;
a main actuator for moving the operating member to the open position or the closed position in response to a pressure of a supplied driving fluid;
an adjustment actuator for adjusting a position of the operating member positioned in the open position; and
a position detecting mechanism for detecting displacement of the operating member with respect to the valve body.

The flow control method of the present invention is a flow rate control method for adjusting the flow rate of a fluid by using a valve device having the above configuration.

The fluid control device of the present invention is a fluid control device comprises a plurality of fluid devices that is arranged,
and the plurality of fluid devices includes a valve device having the above configuration.

The semiconductor manufacturing method of the present invention comprises using a valve device having the above configuration for controlling a flow rate of a process gas in a manufacturing process of a semiconductor device that requires a processing step using the process gas in a sealed chamber.

The semiconductor manufacturing apparatus of the present invention comprises a valve device having the above configuration used for controlling a flow rate of a process gas in a manufacturing process of a semiconductor device that requires a processing step using the process gas in a sealed chamber.

### Advantageous Effects of Invention

According to the present invention, by detecting the displacement of the operating member with respect to the valve body, it is possible to detect the valve opening degree, and it is possible to adjust the flow rate further precisely by the adjustment actuator.

### BRIEF DESCRIPTION OF DRAWINGS

FIG. 1A is a longitudinal cross-sectional view of a valve device according to an embodiment of the present invention, which is a sectional view along line la-la of FIG. 1B.

FIG. 1B is a top view of the valve device in FIG. 1A.

FIG. 1C is an enlarged cross-sectional view of the actuator portion of the valve device in FIG. 1A.

FIG. 1D is an enlarged cross-sectional view of the actuator portion along line 1D-1D of FIG. 1B.

FIG. 1E is an enlarged cross-sectional view in a circle A in FIG. 1A.

FIG. 2 is an explanatory diagram showing the operation of the piezoelectric actuator.

FIG. 3 is a schematic diagram showing an exemplary application of the valve device according to an embodiment of the present invention to a process gas control system of the semiconductor manufacturing apparatus.

FIG. 4 is a functional block diagram showing a schematic configuration of a control system.

FIG. 5 is an enlarged cross-sectional view of a main part for explaining the fully closed status of the valve device in FIG. 1A.

FIG. 6 is an enlarged cross-sectional view of a main part for explaining the fully open status of the valve device in FIG. 1A.

FIG. 7 is a diagram for explaining the main cause of the occurrence of the change with time of the flow rate.

FIG. 8A is an enlarged cross-sectional view of a main part for explaining the state when the flow rate of the valve device in FIG. 1A is adjusted (when the flow rate is decreased).

FIG. 8B is an enlarged cross-sectional view of a main part for explaining a state when the flow rate of the valve device in FIG. 1A is adjusted (when the flow rate is increased).

FIG. 9 is an external perspective view showing an example of the fluid control device.

### DESCRIPTION OF EMBODIMENTS

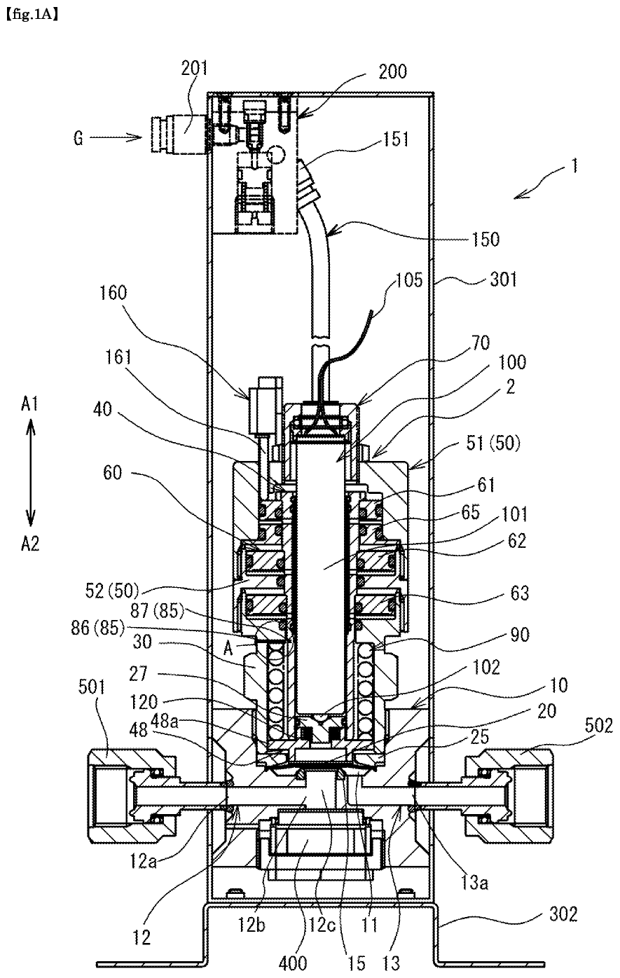

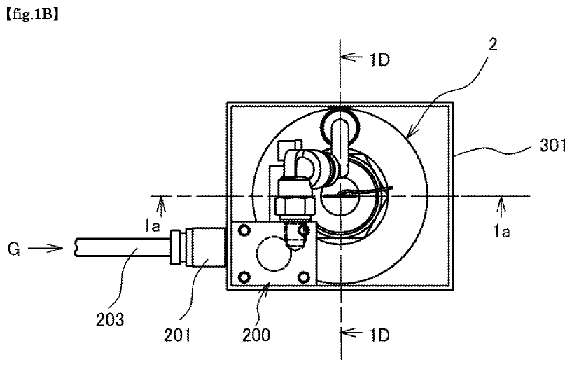

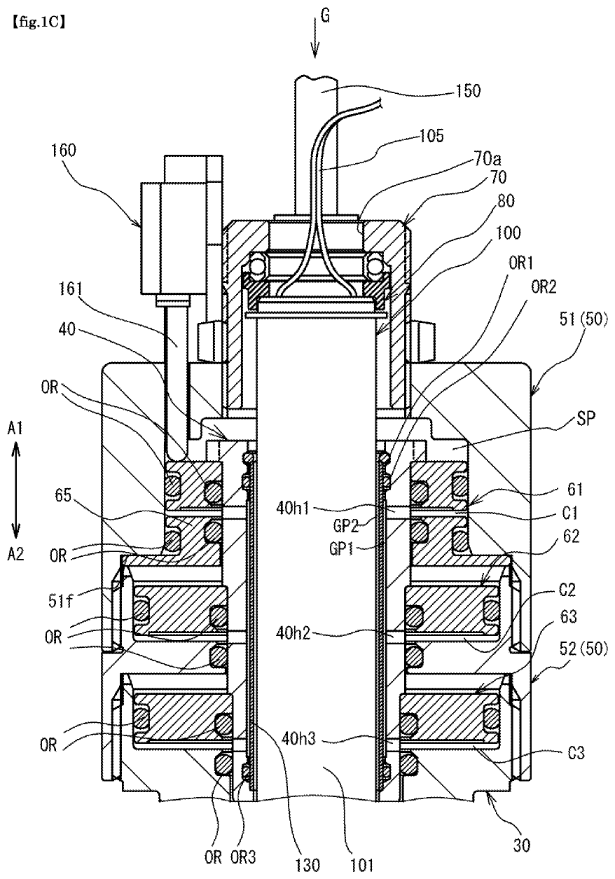

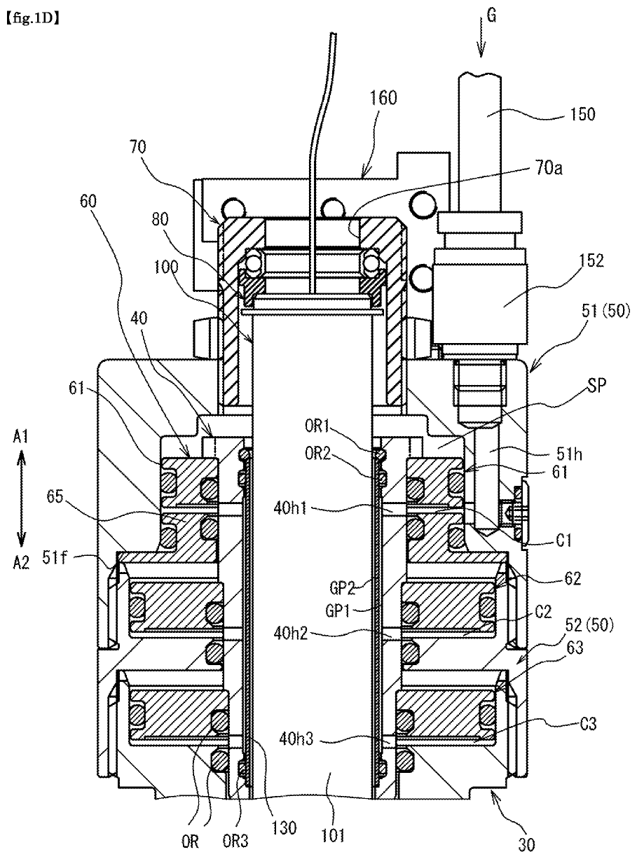

FIG. 1A is a cross-sectional view showing the configuration of the valve device 1 according to an embodiment of the present invention, showing a state in which the valves are fully closed. FIG. 1B is a top view of the valve device 1, FIG. 1C is an enlarged longitudinal sectional view of the actuator portion of the valve device 1, FIG. 1D is an enlarged longitudinal sectional view of the actuator portion in a direction 90 degrees different from FIG. 1C, and FIG. 1E is an enlarged sectional view in a circle A in FIG. 1A. In the following explanation, A1 in FIG. 1A is defined as an upward direction, and A2 is defined as a downward direction.

The valve device 1 has a housing box 301 provided on a support plate 302, a valve main unit 2 installed in the housing box 301, and a pressure regulator 200 installed in the ceiling portion of the housing box 301.

In FIGS. 1A to 1E, 10 indicates a valve body, 15 indicates a valve sheet, 20 indicates a diaphragm, 25 indicates a presser adapter, 27 indicates an actuator receiver, 30 indicates a bonnet, 40 indicates an operating member, 48 indicates a diaphragm presser, 50 indicates a casing, 60 indicates a main actuator, 70 indicates an adjusting body, 80 indicates an actuator presser, 85 indicates a position detecting mechanism, 86 indicates a magnetic sensor, 87 indicates a magnet, 90 indicates a coil spring, 100 indicates a piezoelectric actuator as an adjustment actuator, 120 indicates a disc spring, 130 indicates, a partition wall member, 150 indicates a supply pipe, 160 indicates a limit switch, OR indicates an O-ring as an seal member, and G indicates compressed air as a driving fluid. The driving fluid is not limited to compressed air, and other fluids may be used.

The valve body 10 is made of a metal such as stainless steel, and defines flow paths 12, 13. The flow path 12 has, at one end, an opening 12 a which opens at one side of the valve body 10, and a pipe joint 501 is connected to the opening 12a by welding. In the flow path 12, the other end 12b is connected to the flow path 12c extending in the vertical directions A1, A2 of the valve body 10. The upper end portion of the flow path 12c is opened at the upper surface side of the valve body 10, the upper end portion is opened at the bottom surface of the recess 11 formed on the upper surface side of the valve body 10, and the lower end portion is opened at the lower surface side of the valve body 10. A pressure sensor 400 is provided at the opening on the lower end side of the flow path 12c to close the opening on the lower end side of the flow path 12c.

A valve seat 15 is provided around the opening of the upper end portion of the flow path 12c. The valve seat 15 is made of synthetic resin (PFA, PA, PI, PCTFE, etc.) and is fitted and fixed to the mounting groove provided in the opening periphery of the upper end side of the flow path 12c. In the present embodiment, the valve seat 15 is fixed in the mounting groove by caulking.

The flow path 13 has one end opened at the bottom surface of the recess 11 of the valve body 10, and has, at the other end, an opening 13a which opens at the other side of the valve body 10 opposite to the flow path 12, and a pipe joint 502 is connected to the opening 13a by welding.

The diaphragm 20 is disposed above the valve seat 15, while defining a flow path communicating the flow path 12c and the flow path 13, the central portion thereof is moved up and down to contact to and separate from the valve seat 15, to open and close a gateway between the flow paths 12 and 13. In the present embodiment, the diaphragm 20 has a natural spherical shell shape in which an upwardly convex arc shape is formed by upwardly bulging the central portion of a metal sheet and a nickel-cobalt alloy sheet such as special stainless steel. The diaphragm 20 is formed by laminating three sheets of special stainless steel and one sheet of nickel-cobalt alloy.

The diaphragm 20 is pressed toward a protruding portion side of the valve body 10 via a stainless alloy presser adapter 25 and is held and fixed in an air-tight state by placing the outer peripheral edge portion of the diaphragm 20 on a protruding portion formed on the bottom of the recess 11 of the valve body 10 and screwing the lower end portion of the bonnet 30 inserted into the recess 11 into the screw portion of the valve body 10. As the nickel-cobalt alloy thin film, those having other configurations can be used as a diaphragm which is arranged to the gas contact side.

An operating member 40 is a member for operating the diaphragm 20 so as to open and close the gateway between the flow path 12 and the flow path 13, and is formed in a substantially cylindrical shape, in which the upper end side is open. The operating member 40 is fitted to the inner peripheral surface of the bonnet 30 via an O-ring OR (see FIGS. 1C, 1D), and is movably supported in the vertical directions A1 and A2.

On the lower end surface of the operating member 40, a diaphragm presser 48 is mounted, which has a holding portion made of a synthetic resin such as polyimide and abutting against the central portion of the upper surface of the diaphragm 20.

A coil spring 90 is provided between the upper surface of the flange portion 48a formed on the outer peripheral portion of the diaphragm presser 48 and the ceiling surface of the bonnet 30, and the operating member 40 is constantly urged downward A2 by the coil spring 90. Therefore, when the main actuator 60 is not activated, the diaphragm 20 is pressed against the valve seat 15, and the gateway between flow path 12 and flow path 13 is closed.

Between the lower surface of the actuator receiver 27 and the upper surface of the diaphragm presser 48, a disc spring 120 is provided as an elastic member.

A casing 50 consists of an upper casing member 51 and a lower casing member 52, a screw of the lower end portion of the inner periphery of the lower casing member 52 is screwed with a screw of the upper end portion of the outer periphery of the bonnet 30. Further, a screw of the lower end portion of the inner periphery of the upper casing member 51 is screwed with a screw of the upper end portion of the outer periphery of the lower casing member 52.

An annular bulkhead 65 is fixed between the upper end of the lower casing member 52 and the opposing surface 51f of the upper casing member 51. Between the inner peripheral surface of the bulkhead 65 and the outer peripheral surface of the operating member 40 and between the outer peripheral surface of the bulkhead 65 and the inner peripheral surface of the upper casing member 51 are respectively sealed by O-rings OR.

The main actuator 60 has annular first to third pistons 61, 62, 63. The first to third pistons 61, 62, and 63 are fitted to the outer peripheral surface of the operating member 40 and are movable in the vertical directions A1 and A2 together with the operating member 40. Between the inner peripheral surfaces of the first to third pistons 61, 62, 63 and the outer peripheral surface of the operating member 40, and between the outer peripheral surfaces of the first to third pistons 61, 62, 63 and the upper casing member 51, the lower casing member 52, and the inner peripheral surface of the bonnet 30 are sealed with a plurality of O-rings OR.

As shown in FIGS. 1C and 1D, a cylindrical partition wall member 130 is fixed to the inner peripheral surface of the operating member 40 so as to have a gap GP1 with the inner peripheral surface of the operating member 40. The gap GP1 is sealed by a plurality of O-rings OR1˜OR3 provided between the outer peripheral surface of the upper end side and the lower end side of the partition wall member 130 and the inner peripheral surface of the operating member 40, thereby forming a flow passage of the compressed air G as a driving fluid. The flow passage formed by the gap GP1 is concentrically arranged with a piezoelectric actuator 100. A gap GP2 is formed between a casing 101 and the partition wall member 130 of the piezoelectric actuator 100 to be described later.

As shown in FIG. 1D, the pressure chambers C1 to C3 are formed below the lower surfaces of the first to third pistons 61, 62, and 63, respectively.

Flow passages 40h1, 40h2, and 40h3 are formed to penetrate radially through the operating member 40 at positions communicating with the pressure chambers C1, C2, and C3. The flow passages 40h1, 40h2, 40h3 are each a plurality of flow passages formed at equal intervals in the circumferential direction of the operating member 40. The flow passages 40h1, 40h2, and 40h3 are each connected to the flow passages formed by the gap GP1.

The upper casing member 51 of the casing 50 is formed with a flow passage 51h which opens at the upper surface and extends in the vertical directions A1 and A2 and communicates with the pressure chamber C1. A supply pipe 150 is connected to the opening of the flow passage 51h via a pipe joint 152. Thus, the compressed air G supplied from the supply pipe 150 is supplied to the pressure chambers C1, C2, and C3 through the flow passages described above.

Space SP above the first piston 61 in the casing 50 is connected to the atmosphere through a through hole 70a of the adjusting body 70.

As shown in FIG. 1C, a limit switch 160 is installed on the casing 50 and a movable pin 161 penetrates the casing 50 and is in contact with the upper surface of the first piston 61. The limit switch 160 detects the amount of movement of the first piston 61 (operating member 40) in the vertical directions A1, A2 in response to the movable pin 161.

### Position Detection Mechanism

As shown in FIG. 1E, the position detecting mechanism 85 is provided on the bonnet 30 and the operating member 40, and includes a magnetic sensor 86 as a fixed portion embedded along the radial direction of the bonnet 30, and a magnet 87 as a movable portion embedded in a part of the circumferential direction of the operating member 40 so as to face the magnetic sensor 86.

In the magnetic sensor 86, a wiring 86a is led out to the outside of the bonnet 30, the wiring 86a is composed of a feed line and a signal line, and the signal line is electrically connected to a control unit 300 to be described later. Examples of the magnetic sensor 86 include those utilizing a Hall element, those utilizing a coil, those utilizing an AMR element whose resistance value changes depending on the strength and orientation of the magnetic field, and the like, and position detection can be made non-contact by combining with the magnet.

The magnet 87 may be magnetized in the vertical directions A1, A2, or may be magnetized in the radial direction. The magnet 87 may be formed in a ring shape.

In the present embodiment, the magnetic sensor 86 is provided on the bonnet 30 and the magnet 87 is provided on the operating member 40, but it is not limited thereto, it can be appropriately modified. For example, the magnetic sensor 86 may be provided on the presser adapter 25, and the magnet 87 may be provided at a facing position on a flange portion 48a formed on the outer periphery of the diaphragm presser 8. It is preferable to install the magnet 87 on the side movable with respect to the valve body 10, and install the magnetic sensor 86 on the valve body 10 or on the side not movable with respect to the valve body 10.

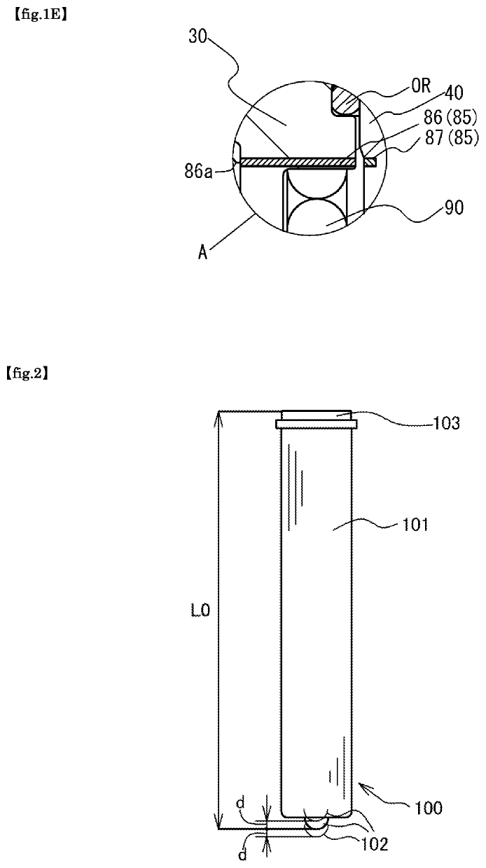

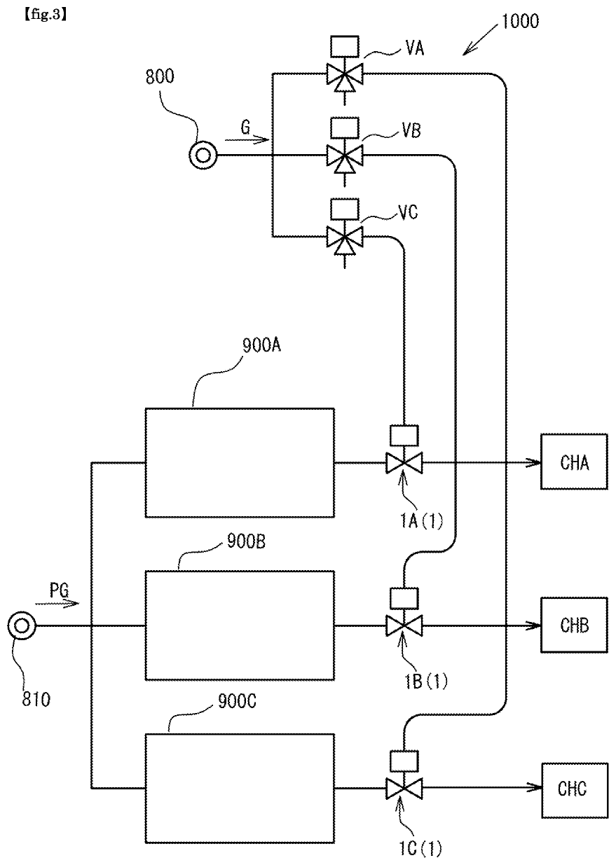

Here, the operation of the piezoelectric actuator 100 will be described with reference to FIG. 2.

The piezoelectric actuator 100 includes a laminated piezoelectric element (not shown) in the cylindrical casing 101 shown in FIG. 2. The casing 101 is made of a metal such as stainless steel alloy, the end surface of the hemispherical tip end portion 102 side and the end surface of the base end portion 103 side is closed. By applying a voltage to the laminated piezoelectric elements to extend them, the end surface of the casing 101 on the tip end portion 102 side is elastically deformed, and the hemispherical tip end portion 102 is longitudinally displaced. Assuming that the maximum stroke of the laminated piezoelectric element is 2d, the total length of the piezoelectric actuator 100 becomes L0 by applying a predetermined voltage V0 at which the elongation of the piezoelectric actuator 100 becomes d in advance. Then, when a voltage higher than the predetermined voltage V0 is applied, the total length of the piezoelectric actuator 100 becomes L0+d at the maximum, and when a voltage lower than the predetermined voltage V0 (including no voltage) is applied, the total length of the piezoelectric actuator 100 becomes L0−d at the minimum. Therefore, the total length from the tip end portion 102 to the base end portion 103 can be expanded and contracted in the vertical directions A1 and A2. In the present embodiment, the tip end portion 102 of the piezoelectric actuator 100 has a hemispherical shape, but the present invention is not limited thereto, and the tip end portion may be a flat surface.

As shown in FIGS. 1A and 1C, the power supply to the piezoelectric actuator 100 is performed by a wiring 105. The wiring 105 is led out to the outside through a through hole 70a of the adjusting body 70.

As shown in FIGS. 1C and 1D, the vertical position of the base end portion 103 of the piezoelectric actuator 100 is defined by the lower end surface of the adjusting body 70 via the actuator presser 80. In the adjusting body 70, a screw portion provided on the outer peripheral surface of the adjusting body 70 is screwed into a screw hole formed in the upper portion of the casing 50, and by adjusting the positions of the adjusting body 70 in the vertical directions A1, A2, it is possible to adjust the position of the piezoelectric actuator 100 in the vertical directions A1, A2.

The tip end portion 102 of the piezoelectric actuator 100 is in contact with a conical receiving surface formed on the upper surface of the disk-shaped actuator receiver 27 as shown in FIG. 1A. The actuator receiver 27 is movable in the vertical directions A1, A2.

The pressure regulator 200 has a primary side connected to a supply pipe 203 via a pipe joint 201, and a secondary side connected to a pipe joint 151 provided at the tip end portion of a supply pipe 150.

The pressure regulator 200 is a well-known poppet valve type pressure regulator, although a detailed description thereof will be omitted, it is controlled so that the secondary pressure becomes a preset adjusted pressure by reducing the high-pressure compressed air G supplied through the supply pipe 203 to the desired pressure. When the pressure of the compressed air G supplied through the supply pipe 203 fluctuate due to pulsation or disturbance, this fluctuation is suppressed and output to the secondary side.

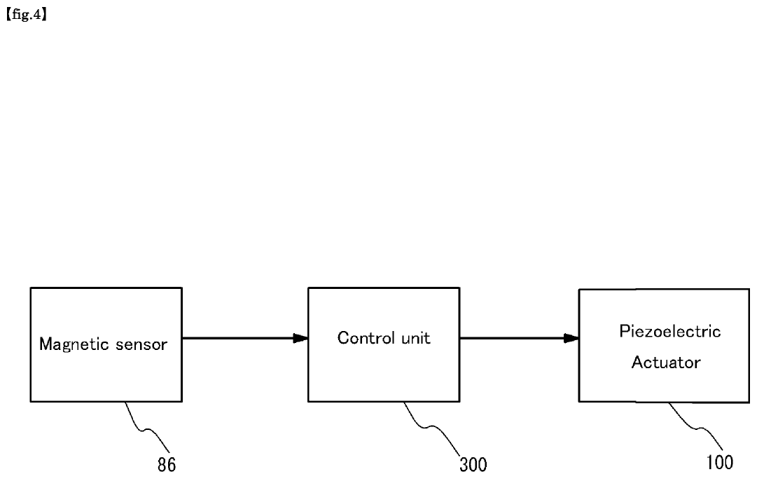

FIG. 3 shows an example in which the valve device 1 according to the present embodiment is applied to a process gas control system of a semiconductor manufacturing apparatus.

The semiconductor manufacturing apparatus 1000 in FIG. 3 is, for example, an apparatus for executing a semiconductor manufacturing process by the ALD method, 800 denotes a supply source of compressed air G, 810 denotes a supply source of process gas PG, 900A to 900C denote fluid control devices, VA to VC denote open-close valves, 1A to 1C denote valve devices according to the present embodiment, and CHA to CHC denote process chambers.

In the semiconductor manufacturing process using the ALD method, it is necessary to precisely adjust the flow rate of the process gases, and it is also necessary to secure the flow rate of the process gases along with increase of the diameter of the substrate.

Fluid control devices 900A to 900C constitutes an integrated gas system that integrates various fluid devices such as open-close valves, regulators, and mass flow controllers to supply precisely measured process gas PG to each of the processing chambers CHA to CHC.

Valve devices 1A to 1C precisely control the flow rate of the process gas PG from the fluid control devices 900A to 900C by opening and closing the diaphragm valve 20 described above, and supply them to the processing chambers CHA to CHC, respectively. Open-close valves VA to VC execute supply and shut-off of compressed air G in response to a control command in order to open and close valve devices 1A to 1C.

In semiconductor manufacturing apparatus 1000 as described above, compressed air G is supplied from a common supply source 800, but open-close valves VA to VC are driven independently.

From the common supply source 800, compressed air G having a substantially constant pressure is always output, but when the open-close valves VA to VC are opened and closed independently, the pressure of the compressed air G supplied to the valve devices 1A to 1C is fluctuated due to the effects of pressure loss when the valve is opened and closed, and is not constant.

When the pressure of the compressed air G supplied to the valve devices 1A to 1C fluctuates, there is a possibility that the flow rate adjusting amount by the piezoelectric actuator 100 described above will fluctuate. In order to solve this problem, the pressure regulator 200 described above is provided.

Next, the control unit of the valve device 1 according to the present embodiment will be described referring to FIG. 4.

As shown in FIG. 4, the control unit 300 is configured to receive the detection signal of the magnetic sensor 86 and drives and controls the piezoelectric actuator 100. The control unit 300 includes, for example, hardware such as a processor, a memory, and the like and required software (not shown), and a driver for driving the piezoelectric actuator 100. Specific examples of the control of the piezoelectric actuator 100 by the control unit 300 will be described later.

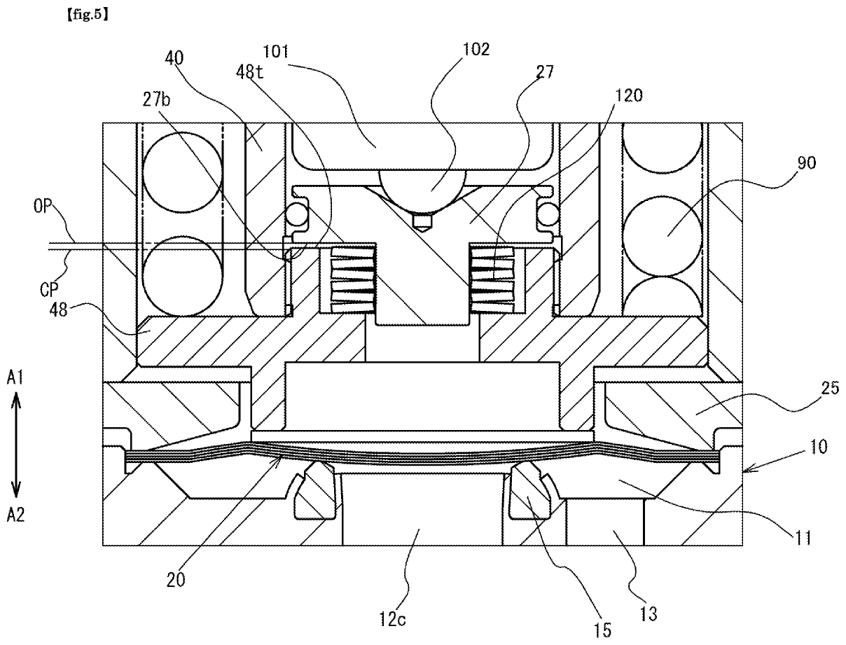

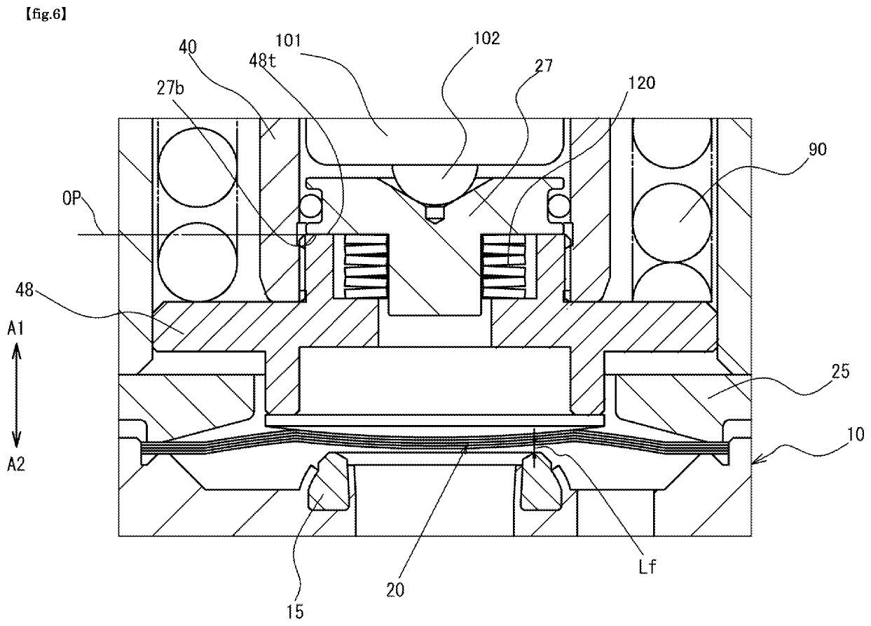

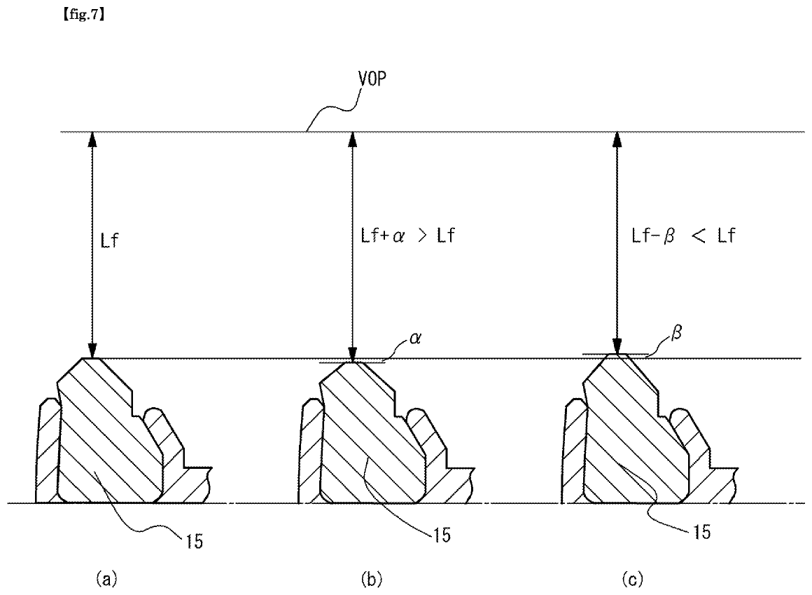

Next, referring to FIGS. 5 and 6, the basic operation of the valve device 1 according to the present embodiment will be described.

FIG. 5 shows the valve device 1 in fully closed status. In the state shown in FIG. 5, the compressed air G is not supplied. In this condition, the disc spring 120 has already been compressed to some extent and elastically deformed, and the restoring force of the disc spring 120 causes the actuator receiver 27 to be constantly biased toward the upward direction A1. Thus, the piezoelectric actuator 100 is also always biased toward the upward direction A1, the upper surface of the base end portion 103 is in a state of being pressed against the actuator presser 80. Thus, the piezoelectric actuator 100 receives the compressive force in the vertical direction A1, A2 and is disposed at a predetermined position relative to the valve body 10. Since the piezoelectric actuator 100 is not connected to any member, it is relatively movable in the vertical direction A1, A2 with respect to the operating member 40.

The number and orientation of disc spring 120 can be appropriately modified depending on the condition. In addition to the disc spring 120, other elastic members such as coil spring and leaf springs can be used, but the use of disc spring makes it easy to adjust spring stiffness, stroking, etc.

As shown in FIG. 5, in a state in which the diaphragm 20 is in contact with the valve seat 15 and the valve is closed, a gap is formed between the regulating surface 27b of the lower surface side of the actuator receiver 27 and the contact surface 48t on the upper surface side of the diaphragm presser 48 mounted on the operating member 40. The position of the regulating surface 27b in the vertical directions A1 and A2 becomes the open position OP when the opening degree is not adjusted. The distance between the regulating surface 27b and the contact surface 48t corresponds to the lift amount Lf of the diaphragm 20. The lift amount Lf defines the opening degree of the valve, that is, the flow rate. The lift amount Lf can be changed by adjusting the position of the adjusting body 70 in the vertical directions A1 and A2. The diaphragm presser 48 (operating member 40) in the condition shown in FIG. 6 is located in the closed position CP, based on the contact surface 48t. When the contact surface 48t moves to a position in contact with the regulating surface 27b of the actuator receiver 27, that is, to the open position OP, the diaphragm 20 is separated from the valve seat 15 by the lift amount Lf.

When the compressed air G is supplied into the valve device 1 through the supply pipe 150, as shown in FIG. 6, a thrust force to push operating member 40 upward A1 is generated in the main actuator 60. The pressure of the compressed air G is set to a value sufficient to move the operating member 40 upward A1 against the biasing force of the downward A2 acting on the operating member 40 from the coil spring 90 and the disc spring 120. When such compressed air G is supplied, as shown in FIG. 6, the operating member 40 moves in the upward direction A1 while further compressing the disc spring 120, the contact surface 48t of the diaphragm presser 48 abuts on the regulating surface 27b of the actuator receiver 27, and the actuator receiver 27 receives a force from the operating member 40 in the upward direction A1. This force acts as a force compressing the piezoelectric actuator 100 in the vertical directions A1, A2 through the tip end portion 102 of the piezoelectric actuator 100. Therefore, the force in the upward direction A1 acting on the operating member 40 is received by the tip end portion 102 of the piezoelectric actuator 100, and the movement in the A1 direction of the operating member 40 is regulated in the open position OP. In this state, the diaphragm 20 is separated from the valve seat 15 by the lift amount Lf described above.

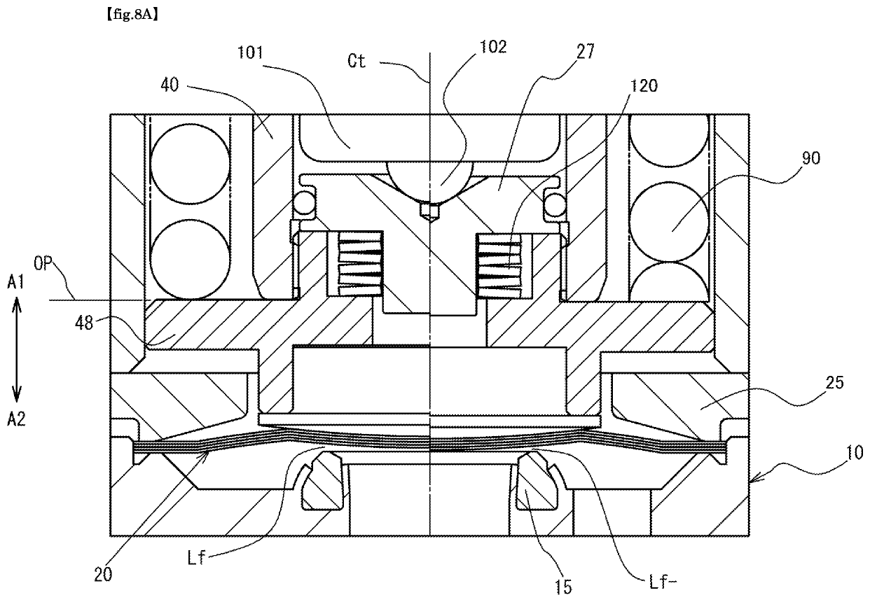

Next, the main causes of flow rate fluctuations in the valve device 1 will be described with reference to FIG. 7.

Deformation of the valve seat 15 is one of the main causes of the flow rate changes with time in the valve device 1. The state shown in FIG. 7(a) is set to the initial state without deformation, and the VOP is set to the open position separated from the seat surface of the valve seat 15 by the lift amount Lf described above.

Since stresses are repeatedly applied to the valve seat 15 by the diaphragm presser 48 through the diaphragm 20, for example, as shown in in FIG. 7(b), the valve seat 15 collapses. Assuming that the deformation amount due to the collapse of the valve seat 15 is a, the valve opening degree is the distance Lf+α between the sheet surface and the open position VOP, and the flow rate is increased as compared with the initial state.

Since the valve seat 15 is exposed to a high temperature atmosphere, as shown in FIG. 7(c), the valve seat 15 is thermally expanded. Assuming that the amount of deformation of the valve seat 15 due to thermal expansion is β, the valve opening degree is the distance Lf−βbetween the sheet surface and the open position VOP, and the flow rate is reduced as compared with the initial state.

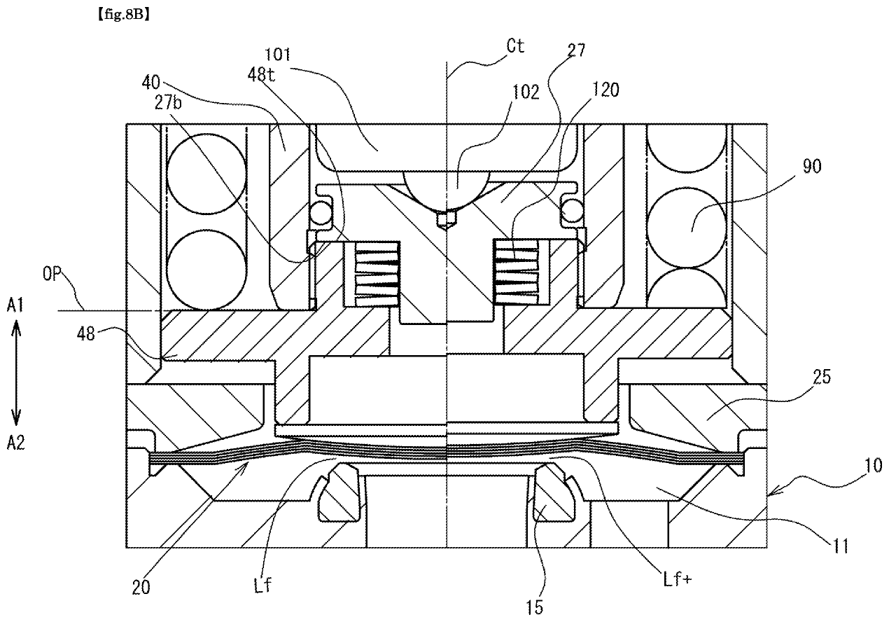

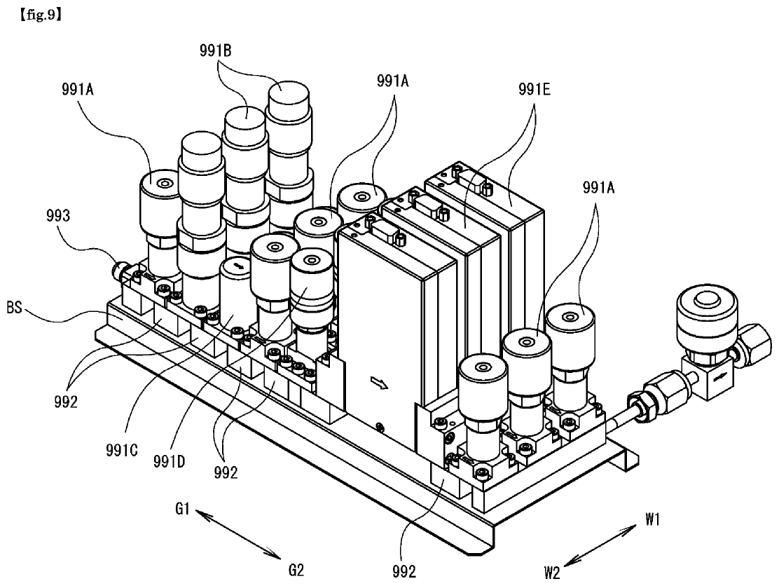

Next, an example of the flow rate adjustment of the valve device 1 will be described with reference to FIGS. 8A and 8B.

First, the position detecting mechanism 85 described above is constantly detecting the relative displacement between the valve body 10 and the magnetic sensor 86 in the state shown in FIGS. 5 and 6. Shown in FIG. 6, the relative positional relationship between the magnetic sensor 86 and the magnet 87 in the valve closed state can be set as the origin position of the position detecting mechanism 85.

Here, the left side of the center line Ct in FIGS. 8A and 8B indicates a state shown in FIG. 5, and the right side of the center line Ct indicates a state after adjusting the position of the vertical direction A1, A2 of the operating member 40.

When adjusting in the direction of reducing the flow rate of the fluid, as shown in FIG. 8A, the piezoelectric actuator 100 is extended to move the operating member 40 downward A2. Thus, the lift amount Lf−after adjustment that is the distance between the diaphragm 20 and the valve seat 15, is smaller than the lift amount Lf before adjustment. The extension amount of the piezoelectric actuator 100 may be set to a deformation amount of the valve seat 15 detected by the position detecting mechanism 85.

When adjusting in the direction of increasing the flow rate of the fluid, as shown in FIG. 8B, the piezoelectric actuator 100 is shortened to move the operating member 40 upward A1. Thus, the lift amount Lf+after adjustment that is the distance between the diaphragm 20 and the valve seat 15 is larger than the lift amount Lf before adjustment. The reduced amount of the piezoelectric actuator 100 may be set to a deformation amount of the valve seat 15 detected by the position detecting mechanism 85.

In the present embodiment, the maximum value of the lift amount Lf of the diaphragm 20 is about 100 to 200 μm, and the adjustment amount by the piezoelectric actuator 100 is about ±20 μm.

That is, the stroke of the piezoelectric actuator 100 cannot cover the lift amount of the diaphragm 20, but by using the main actuator 60 operated by compressed air G and the piezoelectric actuator 100 together, while ensuring the supply flow rate of the valve device 1 with the main actuator 60 having a relatively long stroke, it is possible to precisely adjust the flow rate with the piezoelectric actuator 100 having a relatively short stroke, and since it becomes unnecessary to manually adjust the flow rate by the adjusting body 70 or the like, the flow rate adjusting man-hours are greatly reduced.

According to the present embodiment, since it is possible to precisely adjust flow rate only by changing the voltage applied to the piezoelectric actuator 100, the flow rate adjustment can be executed immediately, and it is also possible to control flow rate in real time.

In the above embodiment, the piezoelectric actuator 100 is used as an adjustment actuator utilizing a passive element that converts a given power into expansion or contraction forces, but the present invention is not limited thereto. For example, an electrically driven material made of a compound that deforms in response to a change in an electric field can be used as an actuator. The shape and size of electrically driven material can be varied by the current or voltage, and the open position of the restricted operating member 40 can be varied. Such an electrically driven material may be a piezoelectric material or an electrically driven material other than a piezoelectric material. When the material is an electrically driven material other than a piezoelectric material, the material may be an electrically driven type polymeric material.

An electrically driven type polymeric material is also referred to as an electroactive polymer material (EAP), and includes, for example, an electric EAP driven by an external electric field or a Coulombic force, a nonionic EAP in which a solvent swelling a polymer is flown by an electric field to deform the polymer, an ionic EAP driven by movement of ions and molecules by an electric field, and any one or a combination thereof can be used.

In the above embodiment, a so-called normally closed type valve is exemplified, but the present invention is not limited to this, and is also applicable to a normally open type valve.

In the above application example, the valve device 1 is used in a semiconductor manufacturing process by the ALD method, but the present invention is not limited to this, and the present invention can be applied to any object requiring precise flow rate control, such as an atomic layer etching (ALE) method.

In the above embodiment, as the main actuator, a piston incorporated in a cylinder chamber operated by gas pressure is used, but the present invention is not limited to this, and any optimum actuator to the control object is selectable.

In the above embodiment, a position detection mechanism including a magnetic sensor and a magnet has been exemplified, but the present invention is not limited thereto, and it is possible to employ a non-contact type position sensor such as an optical position detecting sensor.

Referring to FIG. 9, illustrated is an exemplary fluid control device to which the inventive valve device is applied.

In the fluid control device shown in FIG. 9, a metallic base plate BS is provided which extends in the longitudinal direction G1, G2 and arranged along the width direction W1, W2. Note that W1 represents the front side, W2 represents the back side, G1 represents the upstream side, and G2 represents the downstream side. Various fluid devices 991A to 991E are installed on the base plate BS via a plurality of flow path blocks 992, and a flow path (not shown) through which fluid flows from the upstream side G1 to the downstream side G2 is formed in the plurality of flow path blocks 992.

Here, a “fluid device” is a device used in a fluid control device for controlling the flow of fluids, and the fluid device comprises a body defining a fluid flow path and has at least two flow path ports opening at a surface of the body. Specifically, the fluid devices include open-close valves (2-way valves) 991A, regulators 991B, pressure gauges 991C, open-close valves (3-way valves) 991D, mass flow controllers 991E, and the like, but not limited thereto. An inlet tube 993 is connected to an upstream flow path port of the flow path (not shown).

The present invention can be applied to various valve devices such as the above-mentioned open-close valves 991A, 991D and regulators 991B.

### REFERENCE SIGNS LIST

1, 1A, 1B, 1C: Valve device

2: Valve main unit

10: Valve body

11: Recess

12: Flow path

12a: Opening

12b: Other end

12c, 13: Flow path

15: Valve seat

20: Diaphragm

25: Presser adapter

27: Actuator receiver

27b: Regulating surface

30: Bonnet

40: Operating member

40h1, 40h2, 40h3: Flow passage

48: Diaphragm presser

48a: Flange portion

48t: Contact surface

50: Casing

51h: Flow passage

51: Upper casing member

51f: Opposing surface

52: Lower casing member

60: Main actuator

61: First piston

62: Second piston

63: Third piston

65: Bulkhead

70: Adjusting body

70a: Through hole

80: Actuator presser

85: Position detecting mechanism

86: Magnetic sensor

86a: Wiring

87: Magnet

90: Coil spring

100: Piezoelectric actuator (adjustment actuator)

101: Casing

102: Tip end portion

103: Base end portion

105: Wiring

120: Disc spring

130: Bulkhead member

150: Supply pipe

151, 152: Pipe joint

160: Limit switch

161: Movable pin

200: Pressure regulator

201: Pipe joint

203: Supply pipe

300: Control unit

301: Storage box

302: Support plate

400: Pressure sensor

501, 502: Pipe joint

800, 810: Supply source

900A-900C: Fluid control device

A: Circle

A1: Upward direction

A2: Downward direction

C1-C3: Pressure chamber

CHA, CHB, CHC: Processing chamber

CP: Closed position

Ct: Central line

G: Compressed air (driving fluid)

GP1, GP2: Gap

Lf: Lift amount

OP: Open position

OR: O-ring

PG: Process gas

SP: Space

V0: Predetermined voltage

VA-VC: Open-close valve

VOP: Open position

991A-991E: Fluid device

992: Flow path block

993: Inlet tube

1000: Semiconductor manufacturing apparatus

1. A valve device comprising:
a valve body that defines a flow path through which a fluid flows and an opening that opens externally in a middle of the flow path;
a diaphragm that covers the opening, separates the flow path from the outside, and contacts to and separates from a periphery of the opening to open and close the flow path;
an operating member for operating the diaphragm provided in such a way as to be capable of moving between a closed position in which the diaphragm closes the flow path and an open position in which the diaphragm opens the flow path;
a main actuator for moving the operating member to the open position or the closed position in response to a pressure of a supplied driving fluid;
an adjustment actuator for utilizing a passive element for converting a given power into expanding and contracting forces, and for adjusting a position of the operating member positioned in the open position; and
a position detecting mechanism for detecting displacement of the operating member with respect to the valve body.

2. The valve device according to claim 1, wherein the position detecting mechanism includes a movable portion and a fixed portion,
the movable portion is provided to move together with the operating member,
the fixed portion is provided so as not to move with respect to the valve body.

3. The valve device according to claim 1, wherein a detection signal of the position detecting mechanism is used in a control unit for driving and controlling the adjustment actuator.

4. The valve device according to claim 2, wherein the position detecting mechanism includes a magnet and a magnetic sensor for detecting the strength of a magnetic field corresponding to a relative position of the magnet.

5. The valve device according to claim 1, wherein the main actuator moves the operating member to the open position,
the adjustment actuator adjusts the position of the operating member while a tip end portion of the adjustment actuator receives a force acting on the operating member positioned in the open position by the main actuator and regulates the movement of the operating member.

6. The valve device according to claim 5, wherein an elastic member for urging the adjustment actuator toward the predetermined position and urging the diaphragm toward the valve closing direction is interposed between the operating member and the adjustment actuator.

7. The valve device according to claim 1, wherein the adjustment actuator has a drive source that expands and contracts in response to supply of power.

8. The valve device according to claim 1, wherein the adjustment actuator comprises an actuator utilizing expansion and contraction of piezoelectric elements.

9. The valve device according to claim 8, wherein the adjustment actuator comprises: a casing having a base end portion and a tip end portion; and a piezoelectric element housed in the casing and laminated between the base end portion and the tip end portion, wherein expansion and contraction of the piezoelectric element is utilized to expand and contract the entire length of the casing between the base end portion and the tip end portion.

10. The valve device according to claim 1, wherein the adjustment actuator comprises an actuator having electrically driven polymers as a drive source.

11. A flow control method comprising regulating a flow rate of fluids using the valve device as defined in claim 1.

12. A fluid control device comprising a plurality of fluid devices that is arranged,
wherein the plurality of fluid devices comprises the valve device as defined in claim 1.

13. (canceled)

14. (canceled)
